(19) United States
(12) Patent Application Publication
(10) Pub. No.: US 2026/0221377 A1
(43) Pub. Date: Jul. 30, 2026

(54) Charged Particle Beam Device

(71) Applicant: Hitachi High-Tech Corporation, Minato-ku, Tokyo (JP)

(72) Inventor: Toshiyuki IWAHORI, Tokyo (JP)

(21) Appl. No.: 19/143,450

(22) PCT Filed: Jan. 6, 2023
(86) PCT No.: PCT/JP2023/000219

§ 371 Date: Jun. 26, 2025

(51) Int. Cl. H01J 37/20; H01J 37/147

(52) U.S. Cl. CPC H01J 37/20; H01J 37/147

(57) ABSTRACT

Provided is a charged particle beam device including: a sample chamber whose inside is in a vacuum state; a stage that is installed inside the sample chamber and holds a sample; a stage driving device that drives the stage; a charged particle beam irradiation optical system that irradiates the sample held on the stage with a charged particle beam; a needle that holds a sample piece extracted from the sample by the charged particle beam; and a manipulator that drives the needle, in which the manipulator includes a gripping mechanism that grips the needle, and an attachment and detachment driving device that drives the gripping mechanism to attach and detach the needle.

### TECHNICAL FIELD

The present invention relates to a charged particle beam device such as an FIB device or an FIB-SEM.

### BACKGROUND ART

There is known a charged particle beam device that extracts, from a sample such as a semiconductor wafer, a minute sample piece processed into a shape suitable for observation with, for example, a transmission electron microscope. The charged particle beam device irradiates a sample with a charged particle beam including electrons or ions, cuts out a site to be observed from the sample to produce a sample piece, and transfers the sample to a sample piece holder. When the sample piece is transferred to the sample piece holder, the sample piece is bonded to a tip of a needle (also referred to as a probe) attached to a manipulator by, for example, a deposition gas, and is conveyed from the sample to the sample piece holder by the manipulator (PTL 1 and the like).

### CITATION LIST

### Patent Literature

PTL 1: JP2009-59516A

### SUMMARY OF INVENTION

### Technical Problem

The needle has a tip having a thin and sharp shape on the order of um in order to grip a minute sample piece, and may be damaged by interference with the sample due to an erroneous operation. Further, since the sample piece is generally bonded to the tip of the needle by the deposition gas, the tip of the needle may be deformed or contaminated while the sample piece is repeatedly bonded. Since it is difficult to repair the tip of the extremely thin and sharp needle, it is necessary to replace the needle that is contaminated or the like.

However, the sample chamber in which the needle is used during the operation of the charged particle beam device is in a vacuum state, and generally, the charged particle beam device is stopped to open the sample chamber to the atmosphere, and a worker such as an operator or a service person manually replaces the needle. In this case, not only the worker is burdened with a replacement work, but also the sample chamber needs to be brought into a vacuum state again in order to operate the charged particle beam device after the needle is replaced, so that much labor and time are required until the operation is resumed, and an operation rate of the charged particle beam device is also reduced.

An object of the present invention is to provide a charged particle beam device capable of reducing labor and time required for needle replacement and improving an operation rate.

### Solution to Problem

In order to achieve the above object, the present invention provides a charged particle beam device including: a sample chamber whose inside is in a vacuum state; a stage that is installed inside the sample chamber and holds a sample; a stage driving device that drives the stage; a charged particle beam irradiation optical system that irradiates the sample held on the stage with a charged particle beam; a needle that holds a sample piece extracted from the sample by the charged particle beam; and a manipulator that drives the needle, in which the manipulator includes a gripping mechanism that grips the needle, and an attachment and detachment driving device that drives the gripping mechanism to attach and detach the needle.

### Advantageous Effects of Invention

According to the present invention, it is possible to reduce labor and time required for needle replacement and improve an operation rate.

### BRIEF DESCRIPTION OF DRAWINGS

FIG. 1 is a schematic view of a charged particle beam device according to an embodiment of the present invention.

FIG. 2 is a schematic view of a needle provided in the charged particle beam device according to the embodiment of the present invention.

FIG. 3 is a schematic view of a manipulator provided in the charged particle beam device according to the embodiment of the present invention.

FIG. 4 is a schematic view of a gripping mechanism of the needle of the manipulator provided in the charged particle beam device according to the embodiment of the present invention.

FIG. 5 is a schematic plan view of a needle carrier provided in the charged particle beam device according to the embodiment of the present invention.

FIG. 6 is a schematic side view of the needle carrier provided in the charged particle beam device according to the embodiment of the present invention.

FIG. 7 is a schematic view illustrating a positional relation between the manipulator and the needle carrier at the time of needle replacement.

FIG. 8A is a view illustrating an operation of transferring a used needle from the manipulator to a needle rack.

FIG. 8B is a view illustrating an operation of transferring the used needle from the manipulator to the needle rack.

FIG. 8C is a view illustrating an operation of transferring the used needle from the manipulator to the needle

FIG. 8D is a view illustrating an operation of transferring the used needle from the manipulator to the needle rack.

FIG. 8E is a view illustrating an operation of transferring the used needle from the manipulator to the needle rack.

FIG. 9A is a view illustrating an operation of attaching a replacement needle of the needle rack to the manipulator.

FIG. 9B is a view illustrating an operation of attaching the replacement needle of the needle rack to the manipulator.

FIG. 9C is a view illustrating an operation of attaching the replacement needle of the needle rack to the manipulator.

FIG. 10 is a flowchart illustrating a procedure for controlling the attachment and detachment of the needle by a computer provided in the charged particle beam device according to the embodiment of the present invention.

### DESCRIPTION OF EMBODIMENTS

Hereinafter, an embodiment of the invention will be described with reference to the drawings.

### Charged Particle Beam Device

A charged particle beam device according to the invention is a device for cutting out a minute sample piece from a sample such as a semiconductor wafer by a charged particle beam. In the present embodiment, an FIB-SEM in which a focused ion beam device that irradiates a sample with a focused ion beam (FIB) and a scanning electron microscope that irradiates a sample with an electron beam (EB) are combined will be described as an example of the charged particle beam device. However, the invention is also applicable to other devices as long as the charged particle beam device includes a needle that holds a sample piece. For example, the invention is also applicable to a focused ion beam device having no scanning electron microscope.

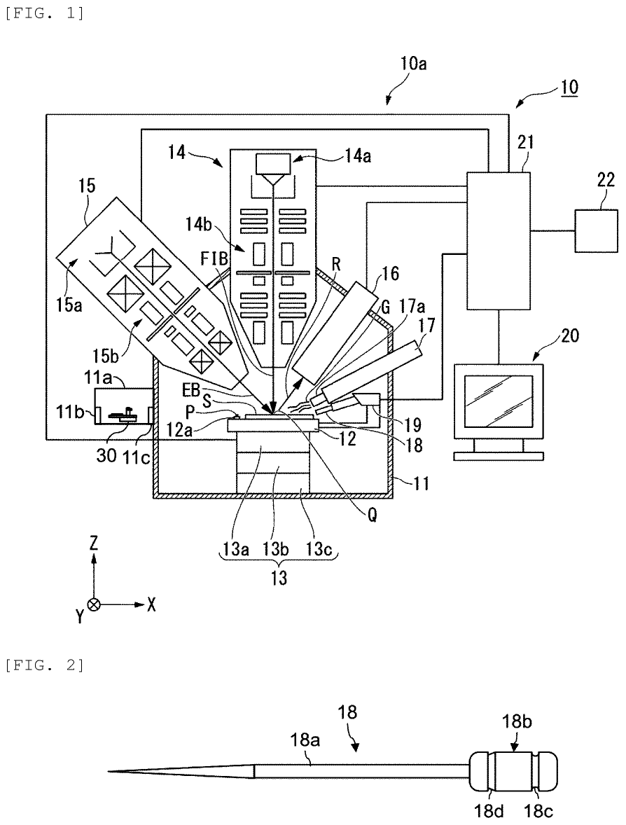

FIG. 1 is a schematic view of a charged particle beam device according to an embodiment of the present invention. A charged particle beam device 10a illustrated in FIG. 1 includes a sample chamber 11, a stage 12, a stage driving device 13, a sample piece holder P, and a focused ion beam irradiation optical system 14. The charged particle beam device 10a includes an electron beam irradiation optical system 15, a detector 16, a gas gun 17, a needle 18, a manipulator 19, a preliminary sample chamber 11a, a needle carrier 30, and a computer 21.

The charged particle beam device 10a can perform various types of processes (an etching process and the like) by sputtering and formation of a deposition film by irradiating a surface of an object with a focused ion beam (a charged particle beam) while scanning the surface. The charged particle beam device 10a can irradiate a sample S with a focused ion beam and extract a sample piece Q (a slice sample, a needle-like sample, or the like) used for transmission observation by, for example, a transmission electron microscope. Further, the charged particle beam device 10a can transfer the extracted sample piece Q to the sample piece holder P using the needle 18, process the sample piece Q placed on the sample piece holder P, and thin the sample piece Q to a desired thickness (for example, 10 nm to 20 nm) suitable for transmission observation. At this time, the charged particle beam device 10a can observe the surface of the object by irradiating the surface of the object such as the sample piece Q or the needle 18 with the focused ion beam FIB or the electron beam EB while scanning the surface.

### Sample Chamber 11

The sample chamber 11 is a chamber having a sealed structure, and is configured to be evacuated by a vacuum pump (not illustrated) during operation of the charged particle beam device 10a to bring the inside into a desired vacuum state and maintain the desired vacuum state.

### Stage 12

The stage 12 is a base that fixes and holds a sample holder (not illustrated), and is installed inside the sample chamber 11. The sample S and the sample piece holder P are fixed to a sample holder. The sample piece holder P is attached to and detached from the sample holder. For example, after the sample piece Q extracted from the sample S is placed on the sample piece holder P, the sample holder is removed from the stage 12 and carried out from the sample chamber 11 to the preliminary sample chamber 11a. The sample piece holder P carried out to the preliminary sample chamber 11a together with the sample holder is removed from the sample holder, is set, for example, in a transmission electron microscope, and is used for fine observation of the sample piece Q.

### Stage Driving Device 13

The stage driving device 13 is a device that drives the stage 12, is accommodated inside the sample chamber 11 together with the stage 12, and displaces the stage 12 according to control signals from the computer 21. The stage driving device 13 includes a translation mechanism 13a, a tilt mechanism 13b, and a rotation mechanism 13c. The translation mechanism 13a is a mechanism that translates the stage 12 in three-dimensional directions along an X-axis, a Y-axis, and a Z-axis. The X-axis and the Y-axis are two horizontal axes orthogonal to each other, and the Z-axis is an axis orthogonal to the X-axis and the Y-axis at an intersection of the X-axis and the Y-axis. The tilt mechanism 13b is a mechanism that rotates the stage 12 around an axis parallel to the X-axis or the Y-axis to tilt the stage 12 with respect to a horizontal plane. The rotation mechanism 13c is a mechanism that rotates the stage 12 around an axis parallel to the Z-axis.

### Focused Ion Beam Irradiation Optical System 14

The focused ion beam irradiation optical system (a charged particle beam irradiation optical system) 14 is a unit that irradiates an object in a predetermined irradiation region (an own scanning range) inside the sample chamber 11 with the focused ion beam FIB (a charged particle beam). The object irradiated with the focused ion beam FIB by the focused ion beam irradiation optical system 14 is the sample S held by the stage 12, the sample piece Q, the needle 18 entering the irradiation region, and the like. The focused ion beam irradiation optical system 14 is fixed to the sample chamber 11 in a posture in which a beam emitting unit (not illustrated) faces the inside of the sample chamber 11 and an optical axis is vertical. The beam emitting unit of the focused ion beam irradiation optical system 14 faces an upper side of the stage 12. In this way, an object such as the sample S fixed to the stage 12 is irradiated with the focused ion beam FIB vertically from above.

Specifically, the focused ion beam irradiation optical system 14 includes an ion source 14a that generates ions and an ion optical system 14b that focuses and deflects the ions extracted from the ion source 14a. As the ion source 14a, for example, a liquid metal ion source using liquid gallium or the like, a plasma type ion source, or a gas field ionization type ion source is used. The ion optical system 14b includes, for example, a first electrostatic lens using a condenser lens or the like, an electrostatic deflector, a second electrostatic lens using an objective lens or the like, and the like. The ion source 14a and the ion optical system 14b are controlled according to control the computer 21. An irradiation position, an irradiation condition, and the like of the focused ion beam FIB are controlled by the computer 21.

### Electron Beam Irradiation Optical System 15

The electron beam irradiation optical system 15 (a charged particle beam irradiation optical system) is a unit that irradiates an object in a predetermined irradiation region (an own scanning range) inside the sample chamber 11 with the electron beam EB (a charged particle beam). The object irradiated with the electron beam EB by the electron beam irradiation optical system 15 is the sample S held by the stage 12, the sample piece Q, the needle 18 entering the irradiation region, and the like. The electron beam irradiation optical system 15 is fixed to the sample chamber 11 in a posture in which a beam emitting unit (not illustrated) faces the inside of the sample chamber 11 and an optical axis is inclined with respect to a horizontal plane. In this way, an object such as the sample S fixed to the stage 12 is obliquely irradiated with an electron ion beam.

Specifically, the Electron Beam Irradiation Optical system 15 includes an electron source 15a that generates electrons and an electron optical system 15b that focuses and deflects the electrons emitted from the electron source 15a. The electron optical system 15b includes an electromagnetic lens, a deflector, and the like. The electron source 15a and the electron optical system 15b are controlled according to control signals from the computer 21. An irradiation position, an irradiation condition, and the like of the electron ion beam are controlled by the computer 21.

The arrangement of the electron beam irradiation optical system 15 may be replaced with that of the focused ion beam irradiation optical system 14, the electron beam irradiation optical system 15 may be disposed vertically, and the focused ion beam irradiation optical system 14 may be disposed obliquely.

### Detector 16

The detector 16 is a unit that detects secondary charged particles R (secondary ions, secondary electrons, and the like) generated from an object by irradiation of a charged particle beam (that is, the focused ion beam FIB or the electron beam EB). The detector 16 detects an intensity of the secondary charged particles R (that is, an amount of the secondary charged particles R) emitted from the object when the object such as the sample S is irradiated with the charged particle beam, and outputs data on a detection amount of the secondary charged particles R. The detector 16 is fixed to the sample chamber 11 such that an incident portion of the secondary charged particles R is located at a position where the amount of the secondary charged particles R can be detected inside the sample chamber 11, for example, at a position obliquely above the irradiation region.

### Gas Gun 17

The gas gun 17 is a unit that supplies the gas G to the surface of the object. The gas gun 17 is fixed to the sample chamber 11 so that a gas injection unit (not illustrated) faces an irradiation region of the charged particle beam inside the sample chamber 11. The gas gun 17 can supply an etching gas, a deposition gas, or the like to the sample S. The etching gas is a gas for selectively promoting the etching of the sample S by the focused ion beam FIB according to the material of the sample S. The deposition gas is a gas for forming a deposition film of a deposit such as a metal or an insulator on a surface of the sample S. For example, the etching is promoted by supplying an etching gas, such as xenon fluoride for the Si-based sample S and water for the organic-based sample S, to the sample S while irradiating the sample S with the focused ion beam FIB. For example, when the deposition gas containing phenanthrene, platinum, carbon, or tungsten is supplied to the sample S while being irradiated with the focused ion beam FIB, a solid component decomposed from the deposition gas adheres to the surface of the sample S to form a deposition film.

### Preliminary Sample Chamber 11a

The preliminary sample chamber 11a is a sample exchange chamber having a sealed structure for carrying the sample S or the like in or out of the sample chamber 11 without reducing a degree of vacuum of the sample chamber 11, and is provided adjacent to the sample chamber 11. Similarly to the sample chamber 11, the preliminary sample chamber 11a is also formed to be evacuated so that the inside can be brought into a desired vacuum state. An internal volume of the preliminary sample chamber 11a is smaller than an internal volume of the sample chamber 11. The preliminary sample chamber 11a is provided with a first gate valve 11b and a second gate valve 11c. A space inside the preliminary sample chamber 11a is separated from a space outside the charged particle beam device 10a via the first gate valve 11b. The space inside the preliminary sample chamber 11a is separated from a space inside the sample chamber 11 via the second gate valve 11c.

When the sample S is replaced, the sample S stored in a sample case (not illustrated) is taken out by a sample transfer robot (not illustrated) in a space outside the charged particle beam device 10a, and is set in a sample holder set inside the preliminary sample chamber 11a via the first gate valve 11b. In addition, the sample piece holder P stored in a cartridge case (not illustrated) is taken out by a cartridge transfer robot (not illustrated) and is attached to the sample holder set inside the preliminary sample chamber 11a. Thereafter, the preliminary sample chamber 11a is evacuated in a state where the first gate valve 11b and the second gate valve 11c are closed, and the second gate valve 11c is opened when the inside of the preliminary sample chamber 11a becomes a predetermined vacuum state. The sample holder to which the sample S and the sample piece holder P are fixed is carried in from the preliminary sample chamber 11a to the sample chamber 11 by a transfer device (not illustrated) and fixed to the stage 12. Carrying out the sample holder from the sample chamber 11 to the preliminary sample chamber 11a is performed in the reverse order of carrying in the sample holder from the preliminary sample chamber 11a to the sample chamber 11.

### Needle 18

FIG. 2 is a schematic view of the needle 18. As illustrated in FIG. 2, the needle 18 is a component that holds the sample piece Q extracted from the sample S by the focused ion beam FIB, and includes a needle body 18a and a grip 18b. The needle body 18a is an elongated component having no unevenness on an outer peripheral surface and having a pointed tip, and the sample piece Q is bonded to the tip of the needle body 18a. The material of the needle body 18a is metal, Si, glass, or the like. The grip 18b is a portion to be gripped by the manipulator 19, and is attached to a proximal end (end opposite to the pointed tip) of the needle body 18a.

The grip 18b is provided with a ring-shaped groove that goes around the outer peripheral surface as an engaging portion 18c that engages with a gripping mechanism 19e (to be described later) of the manipulator 19. Although FIG. 2 illustrates the engaging portion 18c having an arc-shaped cross section cut along a plane including a center line of the needle 18, a shape of the engaging portion 18c is not limited to that in an example illustrated in FIG. 2, and may be any shape suitable for attachment and detachment by the gripping mechanism 19e, and can be appropriately changed together with a configuration of the gripping mechanism 19e.

In addition, the grip 18b includes a notch groove 18d that engages with an engaging portion 37 of a needle rack 32 (to be described later). The notch groove 18d can also be appropriately changed in design as long as the notch groove 18d has a shape that engages with the engaging portion 37 (to be described later) of the needle rack 32. FIG. 2 illustrates a ring-shaped groove that goes around an outer peripheral surface. In the present example, a cross section of the notch groove 18d cut along the plane including the center line of the needle 18 is not a smooth shape, but is a shape having corners, specifically, a triangular shape.

Although a component called a replacement needle 18′ appears in the following description, the replacement needle 18′ is replaced with the needle 18 currently attached to the manipulator 19 and attached to the manipulator 19. For convenience, the replacement needle 18′ is distinguished from the needle 18, but the replacement needle 18′ has the same configuration as the needle 18 illustrated in FIG. 2.

### Manipulator 19

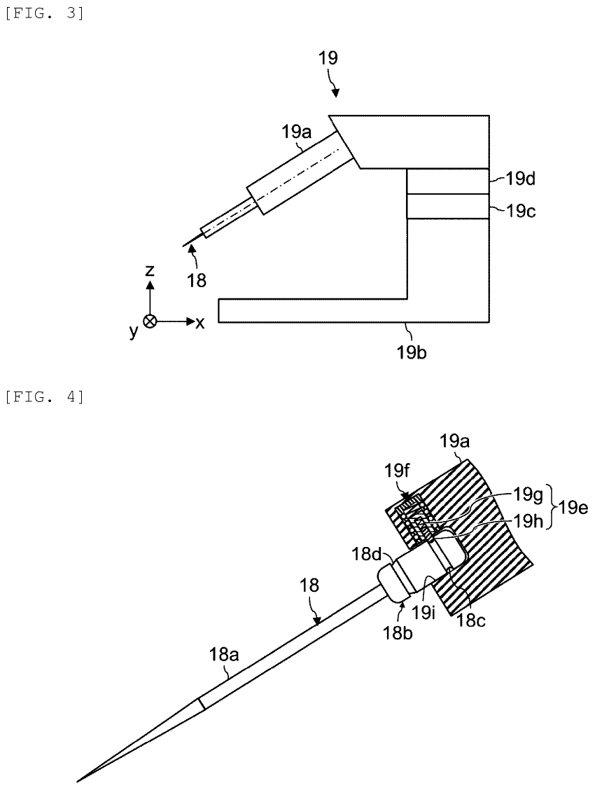

FIG. 3 is a schematic view of the manipulator 19, and FIG. 4 is a schematic view of a gripping mechanism of the needle 18 of the manipulator 19.

The manipulator 19 is a unit that drives the needle 18 to transfer the sample piece Q, and constitutes a sample piece transferring unit together with the needle 18. The manipulator 19 includes an arm 19a that holds the needle 18, and is accommodated inside the sample chamber 11 in a state where the needle 18 is attached to the arm 19a. The manipulator 19 is fixed to the stage 12 via a support 19b and is displaced together with the stage 12. For example, when the stage 12 is tilted by the tilt mechanism 13b, the manipulator 19 is also tilted with respect to the horizontal plane integrally with the stage 12. However, the manipulator 19 may be fixed to, for example, an inner wall surface of the sample chamber 11 instead of the stage 12.

The manipulator 19 includes a translation mechanism 19c and a rotation mechanism 19d, and displaces the needle 18 according to control signals from the computer 21. The translation mechanism 19c and the rotation mechanism 19d are interposed between the support 19b and the arm 19a. By the translation mechanism 19c, the arm 19a and the needle 18 attached to the arm 19a can be translated along an x-axis, a y-axis, and a z-axis with respect to the stage 12. The rotation mechanism 19d allows the arm 19a and the needle 18 attached to the arm 19a to swing around an axis parallel to the z-axis with respect to the stage 12. When the sample piece Q is extracted, the tip of the needle 18 is bonded to an extraction target portion of the sample S fixed to the stage 12 with a deposition gas, the needle 18 is driven by the manipulator 19, and the extracted sample piece Q is transfer to the sample piece holder P.

The x-axis and the y-axis are two horizontal axes orthogonal to each other, and the z-axis is an axis orthogonal to the z-axis and the y-axis at an intersection of the x-axis and the y-axis. An xyz orthogonal coordinate system (FIG. 3) formed by the x-axis, the y-axis, and the z-axis is independent of an XYZ orthogonal coordinate system (FIG. 1) formed by the X-axis, the Y-axis, and the Z-axis. Specifically, the XYZ orthogonal coordinate system is a coordinate system based on the sample chamber 11, and the xyz orthogonal coordinate system is a coordinate system based on the stage 12. Therefore, an xyz coordinate system (FIG. 3) is inclined or rotated with respect to an XYZ coordinate system (FIG. 1) following the stage 12.

As illustrated in FIG. 4, the manipulator 19 includes the gripping mechanism 19e that grips the needle 18, and an attachment and detachment driving device 19f that drives the gripping mechanism 19e to attach or detach the needle 18. An insertion hole 19i into which the grip 18b of the needle 18 is inserted is formed at a tip of the arm 19a of the manipulator 19, and the gripping mechanism 19e illustrated in FIG. 4 is installed on an inner peripheral surface of the insertion hole 19i.

The gripping mechanism 19e is a mechanism that engages with the engaging portion 18c (FIG. 2) of the needle 18 described above to fix the needle 18 to the arm 19a, and in the present embodiment, a configuration in which a latch mechanism is adopted is exemplified. The gripping mechanism 19e illustrated in FIG. 4 includes a cylindrical casing 19g and a tongue 19h that enters and exits the casing 19g. The tongue 19h is pushed by a spring inside the casing 19g to partially protrude from the casing 19g, and is housed in the casing 19g against a spring force when being subjected to an external force.

The attachment and detachment driving device 19f is, for example, a solenoid formed in a cylindrical shape, and is provided in the arm 19a. The gripping mechanism 19e is housed inside a cylindrical attachment and detachment driving device 19f in a state of being subjected to the spring force, and is disposed such that the tongue 19h protrudes from an inner peripheral surface of the insertion hole 19i of the arm 19a to the inside in a radial direction of the insertion hole 19i in a state where the attachment and detachment driving device 19f is demagnetized. When the attachment and detachment driving device 19f is energized, the gripping mechanism 19e (that is, the tongue 19h together with the casing 19g) moves in a direction against the spring force, and the tongue 19h moves from the inside of the insertion hole 19i to the outside in the radial direction of the insertion hole 19i. When such an operation is performed in the state of FIG. 4, the tongue 19h of the gripping mechanism 19e is disengaged from the engaging portion 18c of the needle 18, and the restriction of the needle 18 on the arm 19a is released.

### Needle Carrier 30

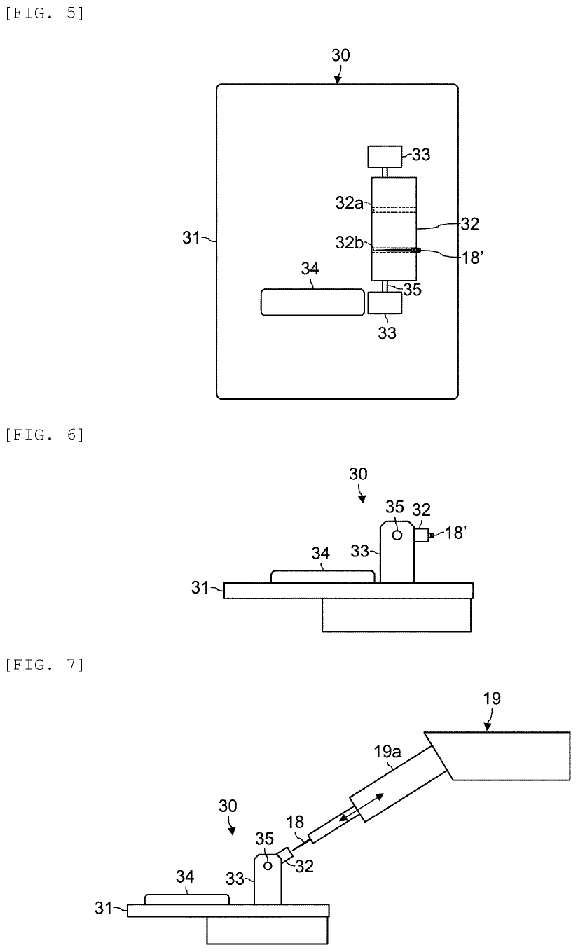

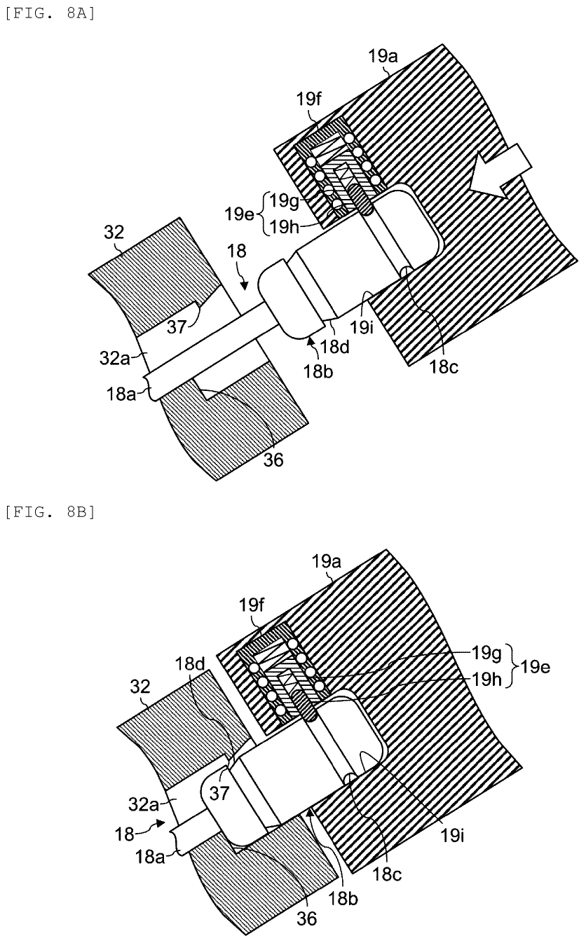

FIG. 5 is a schematic plan view of the needle carrier 30, FIG. 6 is a schematic side view of the needle carrier 30, and FIG. 7 is a schematic view illustrating a positional relation between the manipulator 19 and the needle carrier 30 at the time of needle replacement.

The needle carrier 30 is a component used for needle replacement, and may be attached to the stage 12 similarly to a sample holder including the sample piece holder P. a matter of course, the needle carrier 30 can be manufactured from the beginning as a dedicated product, but since an attachment and detachment mechanism for the stage 12 is common to the sample holder, the needle carrier 30 can be manufactured based on the sample holder. The needle carrier 30 illustrated in FIGS. 5 and 6 includes a base 31, the needle rack 32, a support 33, and a rack driving device 34.

The base 31 is a substructure of the needle carrier 30, and is attached to and detached from the stage 12 by an attachment and detachment mechanism (not illustrated) such as a latch mechanism and is attached to the stage 12 with high positional accuracy, similarly to a sample holder (not illustrated). The support 33 and the rack driving device 34 are fixed to the base 31. The needle rack 32 is rotatably supported by the support 33 via a rotation shaft 35.

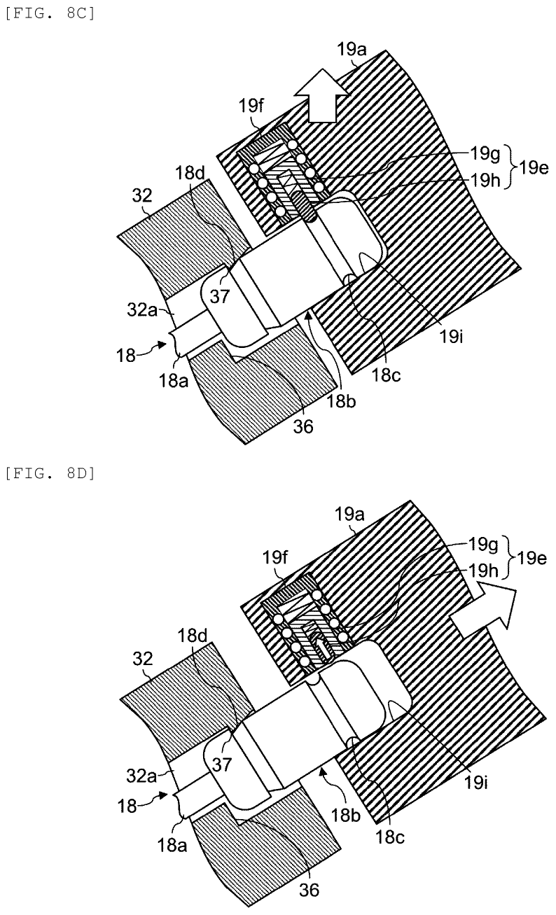

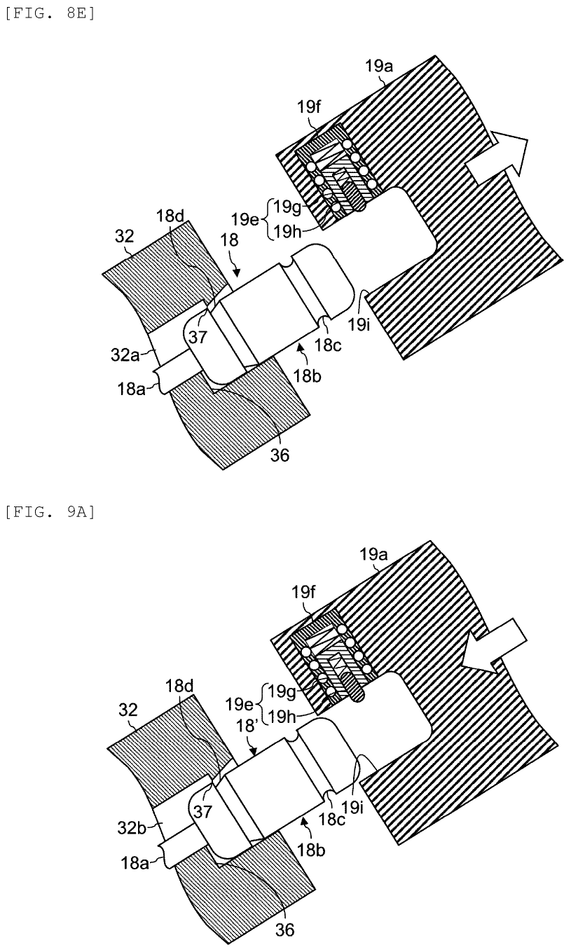

The needle rack 32 includes a first slot 32a which is an empty slot for receiving the used needle 18, and a second slot 32b in which a replacement needle 18′which is a replacement needle attached to the manipulator 19 instead of the used needle is set. The needle rack 32 includes at least one first slot 32a and at least one second slot 32b (one first slot 32a and one second slot 32b in the present embodiment). The first slot 32a and the second slot 32b are insertion holes for the needle 18 (including the replacement needle 18′), and can hold the inserted needle 18. Hereinafter, when the needle 18 is described in this paragraph and the following two paragraphs, the replacement needle 18′is included. As illustrated in FIG. 8A, each of the first slot 32a and the second slot 32b includes a stopper 36 that restricts an insertion position of the needle 18 and the engaging portion 37 that engages with the needle 18.

The needle 18 is inserted into the first slot 32a or the second slot 32b from a tip side (a side opposite to the grip 18b) of the needle body 18a. The stopper 36 illustrated in the present embodiment is a step provided on inner wall surfaces of the first slot 32a and the second slot 32b. When the needle 18 is inserted into the first slot 32a or the second slot 32b, an end surface of the grip 18b facing a tip direction of the needle body 18a hits the stopper 36. In the present embodiment, a case where the stopper 36 is formed by a step is exemplified, but the stopper 36 may have any configuration as long as the stopper 36 can restrict the movement of the needle 18 in an insertion direction in the first slot 32a and the second slot 32b and receive the needle 18, and the design can be appropriately changed.

The engaging portion 37 is an element that engages with the notch groove 18d of the needle 18 when the needle 18 is removed from the manipulator 19, and is formed of a claw-shaped protrusion in the present embodiment. When the needle 18 is removed from the manipulator 19, the needle 18 is driven by the manipulator 19 and inserted into the first slot 32a or the second slot 32b (an empty slot). Thereafter, the gripping mechanism 19e is driven by the attachment and detachment driving device 19f to release the restriction of the needle 18, and before or after this, the needle 18 is driven by the manipulator 19 to engage the notch groove 18d with the engaging portion 37. In this state, when the arm 19a of the manipulator 19 retreats from the needle rack 32, the needle 18 engaged with the engaging portion 37 is pulled out from the manipulator 19 and left in the needle rack 32.

Although FIG. 8A illustrates a claw-shaped protrusion as an example of the engaging portion 37, a latch mechanism such as the gripping mechanism 19e of the manipulator 19 may be employed as the engaging portion 37.

The rack driving device 34 is a device (for example, a motor) that rotates the needle rack 32 with respect to the support 33. Although not particularly illustrated, the base 31 includes a power transmission mechanism and an electronic contact. The stage 12 is provided with an electronic contact (not illustrated) connected to the computer 21, and when the rack driving device 34 is attached to the stage 12, the rack driving device 34 and the electronic contact of the stage 12 are connected. Accordingly, when the rack driving device 34 is attached to the stage 12, the needle carrier 30 is electrically connected to the computer 21 via the electronic contact, and may receive control signals and power supply from the computer 21. The rack driving device 34 is driven by the electric power supplied in this manner, the power of the rack driving device 34 is transmitted to the rotation shaft 35 via a power transmission mechanism, and the needle rack 32 rotates about the rotation shaft 35.

The needle rack 32 has a shape elongated in an extending direction of the first slot 32a and the second slot 32b when viewed in an axial direction of the rotation shaft 35. A basic angle of the needle rack 32 is an angle at which the first slot 32a and the second slot 32b fall down in a horizontal posture and a height of the needle rack 32 is lowered (FIG. 6). At the time of needle replacement, the needle rack 32 is driven by the rack driving device 34 to stand at a predetermined inclination angle (FIG. 7). The predetermined inclination angle is an angle at which inclination angles of the first slot 32a and the second slot 32b coincide with an inclination angle of the needle 18 attached to the manipulator 19.

### Computer 21

The computer 21 is a control device that controls the stage driving device 13, the manipulator 19, a display device 20, and the rack driving device 34, is disposed outside the sample chamber 11, and has a function of attaching and detaching the needle 18 to and from the manipulator 19. The display device 20 that displays image data or the like based on the secondary charged particles R detected by the detector 16, and an input device 22 such as a mouse or a keyboard that outputs a signal according to an input operation of an operator are connected to the computer 21. The computer 21 integrally controls an operation of the charged particle beam device 10a according to a signal output from the input device 22 or an automatic operation control program stored in advance.

The computer 21 converts the detection amount of the secondary charged particles R detected by the detector 16 while scanning the irradiation position of the charged particle beam into a luminance signal associated with the irradiation position. The computer 21 generates image data indicating a shape of the object by the two-dimensional position distribution of the detection amount of the secondary charged particles R. For example, in an absorption current image mode, the computer 21 detects an absorption current flowing through the needle 18 while scanning the irradiation position of the charged particle beam, thereby generating absorption current image data indicating a shape of the needle 18 by the two-dimensional position distribution of the absorption current. Further, the computer 21 causes the display device 20 to display a screen for executing operations such as enlargement, reduction, movement, and rotation of each image data together with each generated image data. In addition, the computer 21 causes the display device 20 to display a screen for performing various settings such as mode selection and processing setting in automatic sequence control.

### Needle Replacement Procedure

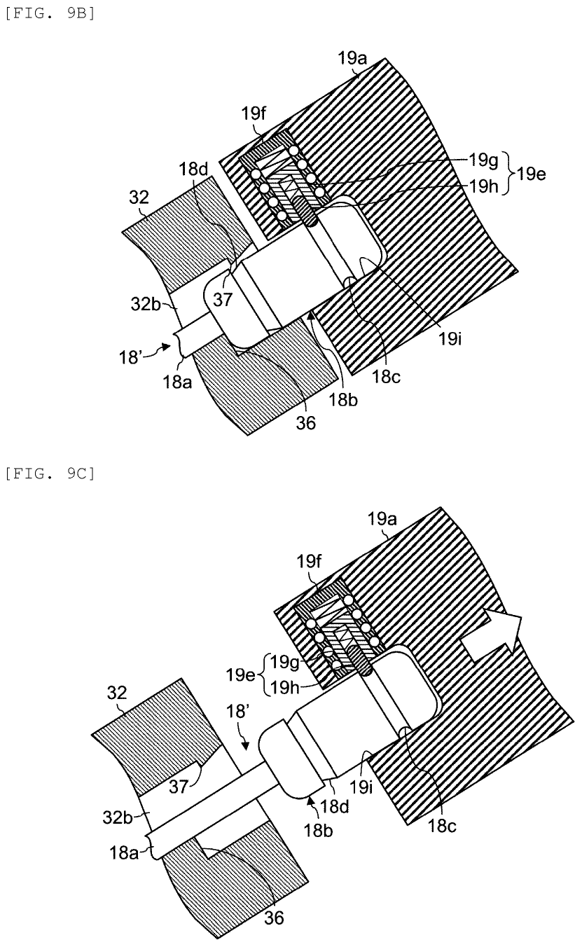

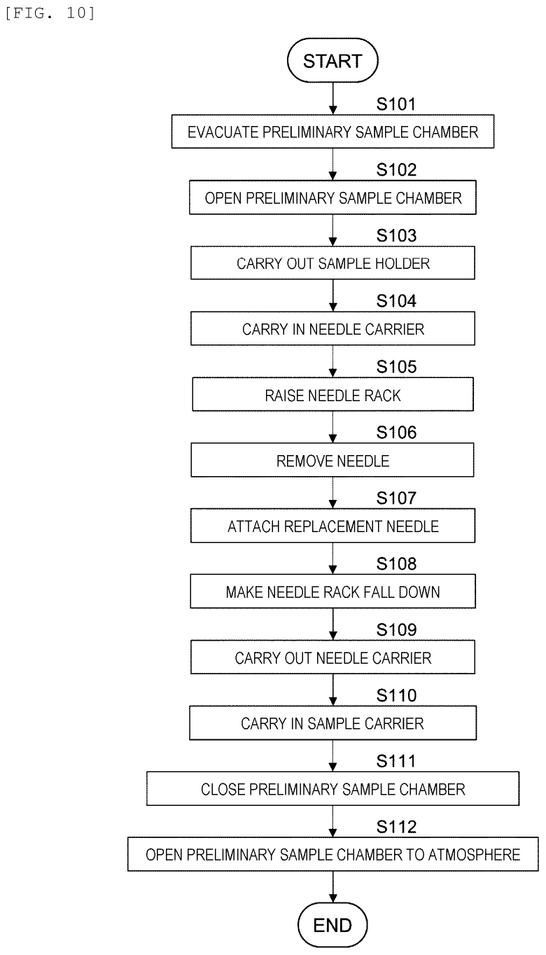

FIGS. 8A to 8E are views illustrating an operation of transferring the used needle 18 from the manipulator 19 to the needle rack 32, and FIGS. 9A to 9C are views illustrating an operation of attaching the replacement needle 18′ of the needle rack 32 to the manipulator 19. FIG. 10 is a flowchart illustrating a procedure for controlling attachment and detachment of the needle 18 by the computer 21.

When the needle 18 is replaced, for example, the needle carrier 30 in which the replacement needle 18′ is set in the second slot 32b is set inside the preliminary sample chamber 11a via the first gate valve 11b (FIG. 1). Thereafter, the computer 21 starts a process illustrated in the flow of FIG. 10 with a signal instructing execution of needle replacement as a trigger. The process of FIG. 10 is executed in a state where the inside of the sample chamber 11 is maintained in a predetermined vacuum state.

### Steps S101 to S105

When the flow of FIG. 10 is started, the computer 21 closes the first gate valve 11b and the second gate valve 11c to evacuate the preliminary sample chamber 11a (step S101). When the preliminary sample chamber 11a becomes a predetermined vacuum state, the computer 21 opens the second gate valve 11c to allow an internal space of the preliminary sample chamber 11a to communicate with an internal space of the sample chamber 11 (step S102).

Thereafter, the computer 21 controls the stage 12 and a transfer device (not illustrated) to remove the sample holder from the stage 12 and carry out the sample holder from the sample chamber 11 to the preliminary sample chamber 11a (step S103). After the sample holder is carried out, the computer 21 controls a transfer device (not illustrated) to carry in the needle carrier 30 from the preliminary sample chamber 11a to the sample chamber 11 and attach the needle carrier 30 to the stage 12 (step S104). When the needle carrier 30 moves between the sample chamber 11 and the preliminary sample chamber 11a, the computer 21 controls the rack driving device 34 to make the needle rack 32 fall down and to lower a height of the needle carrier 30. Accordingly, the needle carrier 30 can pass through the second gate valve 11c having a small opening height. Thereafter, the computer 21 controls the rack driving device 34 to raise the needle rack 32 obliquely, and aligns an angle of the needle rack 32 with an attachment angle of the needle 18 facing the manipulator 19 as illustrated in FIG. 7 (step S105).

### Step S106

After the needle rack 32 is raised obliquely, the computer 21 controls the manipulator 19 and the attachment and detachment driving device 19f to remove the used needle 18 from the manipulator 19 (step S106).

Specifically, first, the computer 21 drives the manipulator 19 to insert the needle into the first slot 32a of the needle rack 32 (FIG. 8A), and brings the grip 18b of the needle 18 into contact with the stopper 36 of the first slot 32a (FIG. 8A). When the stage 12 is movable relative to the manipulator 19, an operation of inserting the needle into the first slot 32a may be performed in combination with the movement of the stage 12 by the stage driving device 13.

Next, the computer 21 drives the manipulator 19 to engage the engaging portion 37 of the first slot 32a with the notch groove 18d of the needle 18 (FIG. 8C). When the stage 12 is movable relative to the manipulator 19, an engagement operation between the engaging portion 37 and the notch groove 18d can also be performed in combination with the movement of the stage 12 by the stage driving device 13.

When the notch groove 18d is engaged with the engaging portion 37, the computer 21 controls the attachment and detachment driving device 19f and the manipulator 19, releases the restriction of the needle 18 by the gripping mechanism 19e, and retracts the manipulator 19 from the needle rack 32 (FIG. 8D). When the manipulator 19 is separated from the needle rack 32 in an axial direction of the needle 18, the needle 18 engaged with the engaging portion 37 is pulled out from the manipulator 19, and the needle 18 is removed from the manipulator 19 and left in the first slot 32a (FIG. 8E). When the stage 12 is movable relative to the manipulator 19, an operation of pulling out the needle 18 can also be performed in combination with the movement of the stage 12 by the stage driving device 13.

### Step S107

After removing the used needle 18 from the manipulator 19, the computer 21 controls the manipulator 19 and the attachment and detachment driving device 19f to attach the replacement needle 18′ to the manipulator 19 (step S107).

Specifically, first, the computer 21 controls the manipulator 19 to cover the grip 18b of the replacement needle 18′ set in the second slot 32b of the needle rack 32 with the insertion hole 19i of the manipulator (FIG. 9A). When the grip 18b received by the stopper 36 is inserted into the insertion hole 19i by a predetermined distance, the tongue 19h of the gripping mechanism 19e is engaged with the engaging portion 18c of the replacement needle 18′ by the spring force, and the replacement needle 18′ is attached to the manipulator 19 (FIG. 9B). When the replacement needle 18′ is attached to the manipulator 19, the computer 21 controls the manipulator 19 to retract the manipulator 19 from the needle rack 32 and pull out the replacement needle 18′ from the second slot 32b (FIG. 9C). When the stage 12 is movable relative to the manipulator 19, an operation of attaching and pulling out the replacement needle 18′ can also be performed in combination with the movement of the stage 12 by the stage driving device 13.

### Steps S108 to S112

When the entire replacement needle 18′ is pulled out from the second slot 32b, the computer 21 controls the rack driving device 34 to make the needle rack 32 fall down horizontally as illustrated in FIG. 6 (step S108). Thereafter, the computer 21 controls the stage 12 and a transfer device (not illustrated) to remove the needle carrier 30 from the stage 12 and carry out the needle carrier 30 together with the used needle 18 from the sample chamber 11 to the preliminary sample chamber 11a (step S109). When the needle carrier 30 moves between the sample chamber 11 and the preliminary sample chamber 11a, the computer 21 controls the rack driving device 34 to make the needle rack 32 fall down and to lower the height of the needle carrier 30. Accordingly, the needle carrier 30 can pass through the second gate valve 11c having a small opening height.

After the needle carrier 30 is carried out, the computer 21 controls a transfer device (not illustrated) to carry in the sample holder from the preliminary sample chamber 11a to the sample chamber 11 and attach the sample holder to the stage 12 (step S110). When the sample holder is attached to the stage 12, the computer 21 closes the second gate valve 11c to separate the internal space of the preliminary material chamber 1a from the internal space of the sample chamber 11 (step S111). Thereafter, the computer 21 releases the vacuum state of the preliminary sample chamber 11a, opens the first gate valve 11b, and opens the preliminary sample chamber 11a (step S112). Accordingly, the needle carrier 30 and thus the used needle 18 can be removed from the preliminary sample chamber 11a.

As described above, the needle replacement is performed inside the sample chamber 11 without releasing the vacuum state of the sample chamber 11.

### Effects

(1) According to the present embodiment, since the manipulator 19 includes the gripping mechanism 19e that grips the needle 18 and the attachment and detachment driving device 19f that drives the gripping mechanism 19e, the needle 18 can be replaced inside the sample chamber 11 while maintaining the vacuum state of the sample chamber 11. Therefore, there is no need to stop the charged particle beam device 10a for needle replacement to open the sample chamber 11 to the atmosphere or to manually replace the needle by the worker. Since the vacuum state of the sample chamber 11 can be maintained at the time of needle replacement, it is not necessary to restore the vacuum state of the sample chamber 11. As a result, according to the charged particle beam device 10a of the present embodiment, it is possible to reduce labor and time required for needle replacement and improve an operation rate.
(2) The needle carrier 30 includes the first slot 32a that is an empty slot and the second slot 32b in which the replacement needle 18′ is set, and can be attached to and detached from the stage 12. By attaching the needle carrier 30 to the stage 12 and controlling the manipulator 19, the used needle 18 can be collected in the first slot 32a, and the replacement needle 18′ in the second slot 32b can be attached to the manipulator 19. Thus, by using the needle carrier 30 detachably attached to the stage 12, the used needle 18 and the replacement needle 18′ can be inserted into and removed from the sample chamber 11 together with the needle carrier 30. A mechanism for carrying in or out the needle carrier 30 to and from the sample chamber 11 can utilize a mechanism for carrying in or out a sample holder generally provided in a charged particle beam device, and can reasonably automate needle replacement.

Further, since the sample holder and the needle carrier 30 can share a mechanism for carrying in or out a sample holder to and from the sample chamber 11, the structures of the sample holder and the needle carrier 30 can be partially shared. Therefore, the needle carrier 30 can be manufactured efficiently and inexpensively by partially diverting the parts and design of the sample holder.

As long as the above-described essential effect (1) is obtained, it is not always necessary to use the needle carrier 30 dedicated to needle replacement. For example, if the sample holder or the sample piece holder P is provided with elements corresponding to the first slot 32a and the second slot 32b, it is also possible to achieve automation of needle replacement using the sample holder or the sample piece holder P.
(3) Since the needle rack 32 of the needle carrier 30 is tilted, the needle rack 32 can fall down horizontally when the needle carrier 30 is carried in and out of the sample chamber 11, and the needle carrier 30 can be smoothly passed through a narrow opening of the second gate valve 11c. In a state where the needle carrier 30 is attached to the stage 12, the needle rack 32 can be raised obliquely in accordance with the inclination of the arm 19a of the manipulator 19 by computer control. Therefore, in order to exchange the needle 18 with the needle rack 32, it is not necessary to expand a movable range of the manipulator 19.

In particular, an observation position of the sample S is a narrow area to which the focused ion beam irradiation optical system 14, the electron beam irradiation optical system 15, the detector 16, and the gas gun 17 approach. Therefore, in consideration of the entry and exit of the sample S into and from the observation position, it is reasonable to adopt a mechanism capable of making the needle rack 32 fall down horizontally to take a thin movement posture as in the present embodiment.

However, a tilt mechanism of the needle rack 32 is not necessarily required as long as the effects (1) and (2) are obtained. For example, in a case where a height dimension of an opening of the second gate valve 11c of the preliminary sample chamber 11a and a space of the observation position of the sample S are sufficient and the needle carrier 30 does not interfere with other structures even in a standing state, the tilt mechanism of the needle rack 32 can be omitted.
(4) The needle 18 (including the replacement needle 18′) is provided with the grip 18b including the engaging portion 18c that engages with the gripping mechanism 19e. The engaging portion 18c can be implemented by, for example, a simple groove, and can achieve the simple gripping mechanism 19e called a latch mechanism and an automatic attachment and detachment mechanism of the needle 18 with respect to the manipulator 19 with a simple configuration.

However, the configurations of the engaging portion 18c, the gripping mechanism 19e, and the attachment and detachment driving device 19f are not limited to the example illustrated in FIG. 4 and the like, and can be appropriately changed in design.
(5) The second slot 32b of the needle rack 32 includes the engaging portion 37 that engages with the needle 18 (including the replacement needle 18′). The engaging portion 37 and the notch groove 18d of the needle 18 engaged with the engaging portion 37 may be formed by a very simple structure as in the present embodiment. With such a simple configuration of the engaging portion 37 and the notch groove 18d, the engaging portion 37 practically functions when the needle 18 is pulled out from the manipulator 19.

However, the configurations of the engaging portion 37 and the notch groove 18d are not limited to the example illustrated in FIG. 8A and the like, and can be appropriately changed in design.

### Modifications

In the above embodiment, a case where the present invention is applied to replacement of the needle 18 for picking up the sample piece Q extracted from the sample S has been described as an example, but the present invention is also applicable to replacement of other needles, for example, a needle for measuring electrical characteristics of a sample. The present invention is also applicable to a charged particle beam device using a plurality of needles inside the sample chamber 11.

Although a configuration in which the needle carrier 30 is directly attached to and detached from the stage 12 has been described as an example, for example, the needle carrier 30 may be attached to and detached from the sample holder instead of the sample piece holder P, and the needle carrier 30 may be attached to and detached from the stage 12 via the sample holder.

In addition, the invention is not limited to the above embodiment, and may include various modifications. For example, the above embodiment has been described in detail to facilitate understanding of the invention, and the invention is not necessarily limited to those including all the configurations described above. A part of a configuration according to the above embodiment may be added to, deleted from, or replaced with another configuration.

Some or all of the above configurations, functions, processing, processing means, and the like may be implemented by hardware such as an integrated circuit. The above configurations, functions, and the like may be implemented by software by a processor interpreting and executing a program for implementing each function. Information such as programs for implementing the respective functions can be stored in various storage media. Examples of the various storage media include recording devices such as a memory, a hard disk, and a solid state drive (SSD), or a flash memory card and a digital versatile disk (DVD).

In the above embodiment, signal input and output lines considered to be necessary for description are shown, and not all signal input and output lines in a product are necessarily illustrated. Actually, almost all configurations may be considered to be connected.

### REFERENCE SIGNS LIST

10a: charged particle beam device
11: sample chamber
11a: preliminary sample chamber
11b: first gate valve
11c: second gate valve
12: stage
13: stage driving device
14: focused ion beam irradiation optical system (charged particle beam irradiation optical system)
15: electron beam irradiation optical system (charged particle beam irradiation optical system)
18: needle
18′: replacement needle
18c: engaging portion
19: manipulator
19e: gripping mechanism
19f: attachment and detachment driving device
21: computer
30: needle carrier
32: needle rack
32a: first slot
32b: second slot
33: support
34: rack driving device
37: engaging portion
EB: electron beam (charged particle beam)
FIB: focused ion beam (charged particle beam)
Q: sample piece
S: sample

1. A charged particle beam device comprising:
a sample chamber whose inside is in a vacuum state;
a stage that is installed inside the sample chamber and configured to hold a sample;
a stage driving device that is configured to drive the stage;
a charged particle beam irradiation optical system that is configured to irradiate the sample held on the stage with a charged particle beam;
a needle that is configured to hold a sample piece extracted from the sample by the charged particle beam; and
a manipulator that drives the needle, wherein
the manipulator includes
a gripping mechanism that grips the needle, and
an attachment and detachment driving device that drives the gripping mechanism to attach and detach the needle.

2. The charged particle beam device according to claim 1, comprising:
a needle carrier that includes a first slot and a second slot and is attachable to the stage;
a replacement needle that is set in the second slot; and
a computer that is configured to control the manipulator, wherein
the computer
controls the manipulator to insert the needle into the first slot,
controls the attachment and detachment driving device to remove the needle from the manipulator and place the needle in the first slot,
controls the manipulator to attach the replacement needle to the manipulator, and
controls the manipulator to pull out the replacement needle from the second slot, and perform needle replacement inside the sample chamber.

3. The charged particle beam device according to claim 2, wherein
the needle carrier includes
a needle rack that includes the first slot and the second slot,
a support that rotatably supports the needle rack, and
a rack driving device that rotates the needle rack with respect to the support, and
the computer controls the rack driving device to raise the needle rack obliquely in accordance with an attachment angle of the needle to the manipulator at the time of needle replacement.

4. The charged particle beam device according to claim 3, comprising
a preliminary sample chamber that is adjacent to the sample chamber, wherein
when the needle carrier moves between the sample chamber and the preliminary sample chamber, the computer controls the rack driving device to make the needle rack fall down and to lower a height of the needle carrier.

5. The charged particle beam device according to claim 2, wherein
the needle and the replacement needle each include an engaging portion that engages with the gripping mechanism.

6. The charged particle beam device according to claim 2, wherein
the second slot includes an engaging portion that engages with the needle and the replacement needle.
